(19) United States
(12) Patent Application Publication
(10) Pub. No.: US 2025/0129478 A1
(43) Pub. Date: Apr. 24, 2025

(54) METHOD OF FORMING FILM LAYER BY USING RECYCLED GAS

(71) Applicant: Innolux Corporation, Miaoli County (TW)

(72) Inventors: Chandra Lius, Miaoli County (TW); Kuan-Feng Lee, Miaoli County (TW)

(73) Assignee: Innolux Corporation, Miaoli County (TW)

(21) Appl. No.: 18/894,018

(22) Filed: Sep. 24, 2024

Related U.S. Application Data
(60) Provisional application No. 63/592,581, filed on Oct. 24, 2023.

(30) Foreign Application Priority Data
Jun. 13, 2024 (CN) 202410762629.3

(51) Int. Cl. C23C 16/455; C23C 16/18; H01L 33/00

(52) U.S. Cl. CPC C23C 16/45593; C23C 16/18; H10H 20/01335

(57) ABSTRACT

A method of forming a film layer by using a recycled gas including the following steps is provided. First, providing a reactor. Next, collecting a tail gas generated after a reaction to form the film layer in a reaction chamber of the reactor. Afterwards, purifying the collected tail gas to obtain a purified precursor. After that, transporting the purified precursor into the reaction chamber.

### CROSS-REFERENCE TO RELATED APPLICATION

This application claims the priority benefit of U.S. provisional application Ser. No. 63/592,581, filed on Oct. 24, 2023, and China application serial no. 202410762629.3, filed on Jun. 13, 2024. The entirety of each of the above-mentioned patent applications is hereby incorporated by reference herein and made a part of this specification.

### BACKGROUND

### Technical Field

The disclosure relates to a method of forming a film layer by using a recycled gas, and particularly relates to a method of forming a film layer by using a recycled gas in a metal-organic chemical vapor deposition (MOCVD) process.

### Description of Related Art

In a metal-organic chemical vapor deposition (MOCVD) process, most of precursors provided to a reaction chamber are not deposited on a substrate after reaction, and these unreacted precursors will be directly extracted from the reaction chamber to form a tail gas and be discharged. In other words, most precursors including rare metals are not effectively utilized in the MOCVD process, which increases the process cost.

### SUMMARY

Some embodiments of the disclosure are directed to a method of forming a film layer by using a recycled gas, which is adapted to reduce process costs.

Some embodiments of the disclosure provide a method of forming a film layer by using a recycled gas including following steps. First, a reactor is provided. Then, a tail gas generated after a reaction of forming the film layer in a reaction chamber of the reactor is collected. Afterwards, the collected tail gas is purified to obtain a purified precursor. Then, the purified precursor is transported into the reaction chamber.

Based on above, the method of forming the film layer by using the recycled gas provided by the disclosure may recycle the unreacted tail gas during the reaction, and may transport the precursor obtained after purifying the tail gas into the reaction chamber again for reaction. In this way, the amount of reaction precursors is reduced to reduce process costs.

To make the aforementioned more comprehensible, several embodiments accompanied with drawings are described in detail as follows.

### BRIEF DESCRIPTION OF THE DRAWINGS

FIG. 1A is a schematic diagram of a reactor according to a first embodiment of the disclosure.

FIG. 1B is a partial schematic cross-sectional view of an embodiment of a recycling chamber in the reactor of FIG. 1A.

FIG. 1C is a partial schematic diagram of an embodiment of a semiconductor element formed by using the reactor of FIG. 1A.

FIG. 1D is a partial schematic diagram of an embodiment of a semiconductor film layer of the semiconductor element in FIG. 1C.

FIG. 1E is a partial schematic diagram of another embodiment of the semiconductor film layer of the semiconductor element in FIG. 1C.

FIG. 2 is a schematic flowchart of using recycled gas to form a film layer in a semiconductor manufacturing process according to an embodiment of the disclosure.

FIG. 3 is a schematic diagram of a reactor according to a second embodiment of the disclosure.

FIG. 4 is a schematic diagram of a reactor according to a third embodiment of the disclosure.

FIG. 5 is a schematic diagram of a reactor according to a fourth embodiment of the disclosure.

FIG. 6 is a schematic diagram of a reactor according to a fifth embodiment of the disclosure.

FIG. 7 is a schematic diagram of a reactor according to a sixth embodiment of the disclosure.

FIG. 8 is a schematic diagram of a reactor according to a seventh embodiment of the disclosure.

FIG. 9 is a schematic diagram of a reactor according to an eighth embodiment of the disclosure.

FIG. 10A is a schematic flowchart of an embodiment of processing tail gas by using a recycling chamber in the reactor of FIG. 1A.

FIG. 10B is a schematic flowchart of another embodiment of processing tail gas by using the recycling chamber in the reactor of FIG. 1A.

FIG. 10C is a schematic flowchart of still another embodiment of processing tail gas by using the recycling chamber in the reactor of FIG. 1A.

FIG. 10D is a schematic flowchart of yet another embodiment of processing tail gas by using the recycling chamber in the reactor of FIG. 1A.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

The disclosure may be understood by referring to the following detailed description and combined with the accompanying drawings. It should be noted that, in order to make the readers easy to understand and concision of the drawings, many of the drawings in the disclosure only depict a part of an electronic device, and certain components in the drawings are not drawn to actual scale. In addition, the number and size of components in the figures are only for illustration and are not intended to limit the scope of the disclosure.

Certain terms are used throughout the specification of the disclosure and the appended claims to refer to specific components. Those skilled in the art should understand that electronic device manufacturers may probably use different names to refer to the same components. This specification is not intended to distinguish between components that have the same function but different names. In the following specification and claims, the terms “including”, “containing”, “having”, etc., are open terms, so that they should be interpreted as meaning of “including but not limited to . . . ”. Therefore, when the terms “including”, “containing”, and/or “having” are used in the description of the disclosure, they specify existence of corresponding features, regions, steps, operations, and/or components, but do not exclude existence of one or more corresponding features, regions, steps, operations, and/or components.

Directional terminology mentioned in the specification, such as “top”, “bottom”, “front”, “back”, “left”, “right”, etc., is used with reference to the orientation of the figures being described. Therefore, the used directional terminology is only illustrative, and is not intended to be limiting of the disclosure. In the figures, the drawings illustrate general characteristics of methods, structures, and/or materials used in specific embodiments. However, these drawings should not be construed as defining or limiting of a scope or nature covered by these embodiments. For example, for clarity's sake, a relative size, a thickness and a location of each film layer, area and/or structure may be reduced or enlarged.

When a corresponding component (for example, a film layer or an area) referred to be “on another component”, the component may be directly located on the another component, or other components probably exist there between. On the other hand, when a component is referred to be “directly on another component”, none other component exits there between. Moreover, when a component is referred to be “on another component”, the two components have an up-down relationship in a top view, and this component may be above or below the another component, and the up-down relationship depends on an orientation of the device.

The terms “about”, “equal to”, “equivalent” or “identical”, “substantially” or “approximately” are generally interpreted as being within a range of 20% of a given value or range, or as being within a range of 10%, 5%, 3%, 2%, 1%, or 0.5% of the given value or range.

The ordinal numbers used in the specification and claims, such as “first”, “second”, etc., are used to modify components, and do not imply and represent the component or these components have any previous ordinal numbers, and do not represent a sequence of one component with another, or a sequence in a manufacturing method. The use of these ordinal numbers is only to make a clear distinction between a component with a certain name and another component with the same name. The same terms may not be used in the claims and the specification, and accordingly, a first component in the specification may be a second component in the claims.

It should be noted that, in the following embodiments, the features of several different embodiments may be replaced, reorganized, and mixed to complete other embodiments without departing from the spirit of the disclosure. As long as the features of the various embodiments do not violate the spirit of the disclosure or conflict with each other, they may be mixed and matched arbitrarily.

The electrical connection or coupling described in the disclosure may refer to direct connection or indirect connection. In the case of direct connection, terminals of components on the two circuits are directly connected or connected to each other by a conductor line segment, and in the case of indirect connection, there are switches, diodes, capacitors, inductors, other suitable components, or a combination of the above components between the terminals of the components on the two circuits, but the disclosure is not limited thereto.

In the disclosure, thickness, length and width may be measured by using an optical microscope, and the thickness may be measured through a cross-sectional image in an electron microscope, but the disclosure is not limited thereto. In addition, any two values or directions used for comparison may have certain errors. If a first value is equal to a second value, it implies that there may be an error of about 10% between the first value and the second value; if a first direction is perpendicular to a second direction, an angle between the first direction and the second direction may be between 80 degrees and 100 degrees; and if the first direction is parallel to the second direction, the angle between the first direction and the second direction may be between 0° and 10°.

The electronic device described in the disclosure may be applied to a display device, a light-emitting device, a backlight device, an antenna device, a sensing device or a splicing device, or a temporary substrate used to assist electronic units to be placed at specific intervals, but the disclosure is not limited thereto. The electronic device may be a bendable or flexible electronic device. The display device may be a non-self-luminous display device or a self-luminous display device. The antenna device may be a liquid crystal type antenna device or a non-liquid crystal type antenna device, and the sensing device may be a sensing device that senses capacitance, light, heat energy or ultrasonic waves, but the disclosure is not limited thereto. The electronic device may include electronic components such as passive components and active components, for example, capacitors, resistors, inductors, diodes, transistors, etc. The diodes may include light-emitting diodes or photodiodes. The light-emitting diodes (LEDs) may include, for example, organic light-emitting diodes (OLEDs), mini LEDs, micro LEDs or quantum dot LEDs, but the disclosure is not limited thereto. The splicing device may be, for example, a display splicing device or an antenna splicing device, but the disclosure is not limited thereto. It should be noted that the electronic device may be any combination of the above, but the disclosure is not limited thereto. In addition, the electronic device may have a rectangular shape, a circular shape, a polygonal shape, a shape with curved edges, or other suitable shapes.

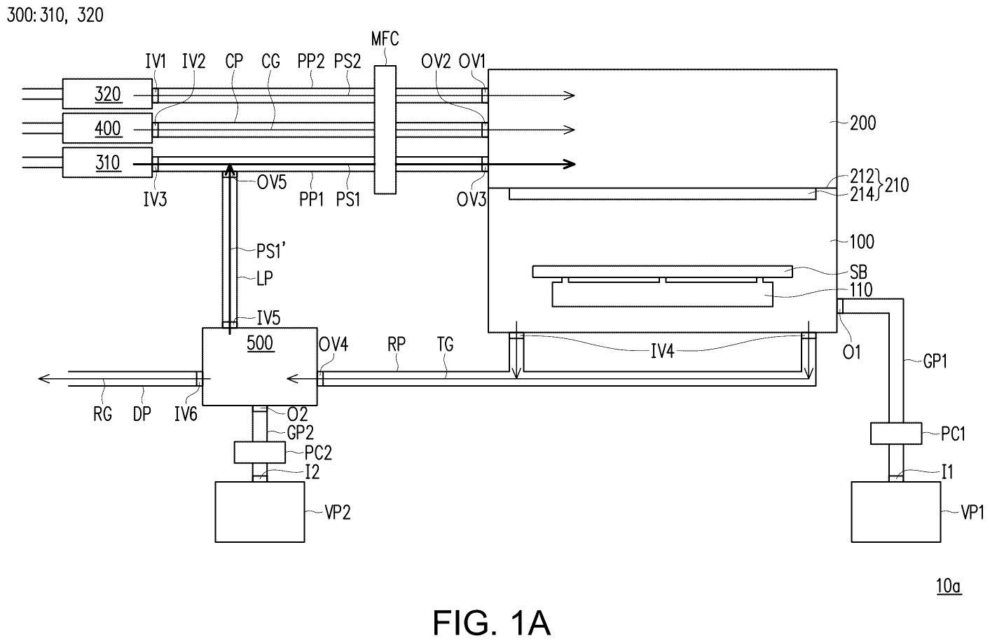

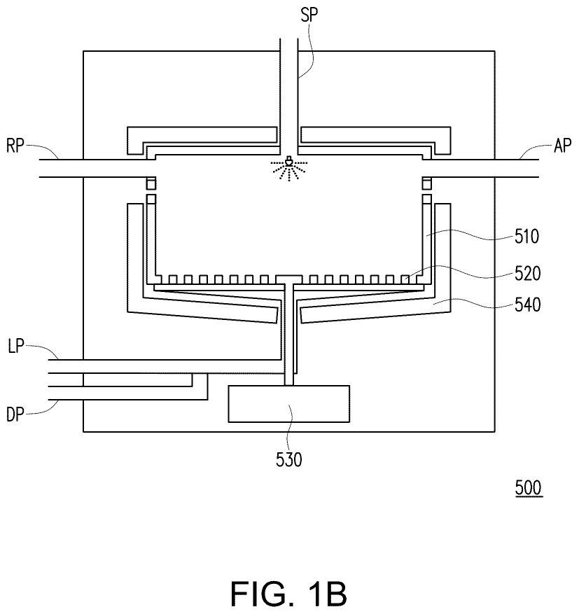

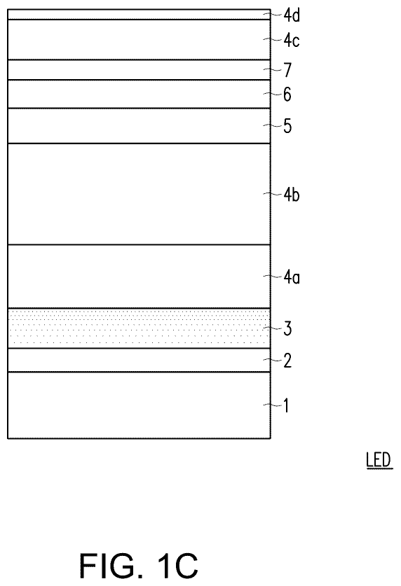

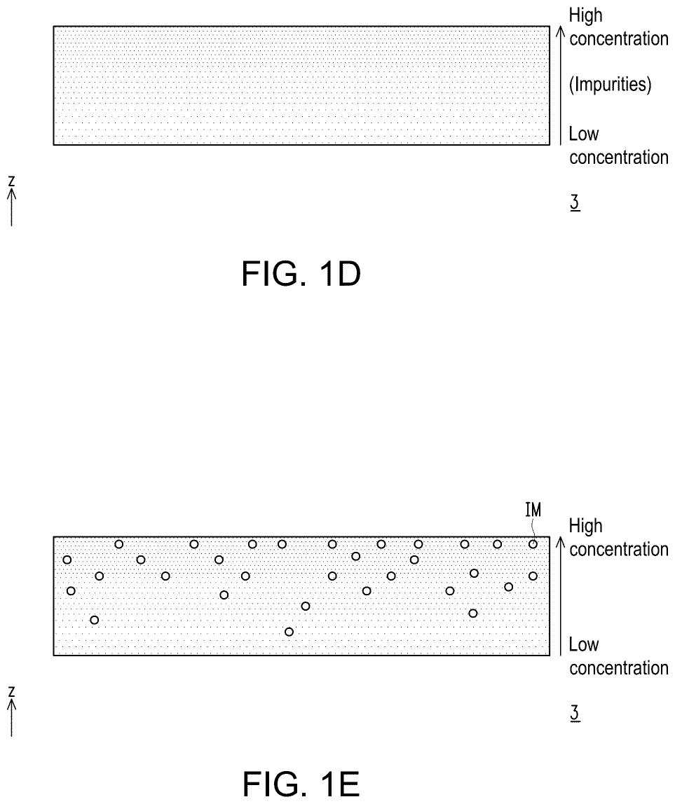

FIG. 1A is a schematic diagram of a reactor according to a first embodiment of the disclosure, and FIG. 1B is a partial schematic cross-sectional view of an embodiment of a recycling chamber in the reactor of FIG. 1A.

Referring to FIG. 1A, which shows that a reactor 10a includes a reaction chamber 100, a gas chamber 200, a precursor source 300, a carrier gas source 400, and a recycling chamber 500. In the embodiment, the reactor 10a is a metal-organic chemical vapor deposition (MOCVD) reactor, but the disclosure is not limited thereto.

The reaction chamber 100 includes, for example, a support platform 110. The support platform 110 is, for example, configured to place at least one substrate SB to be reacted, where the substrate SB may be, for example, a semiconductor substrate, but the disclosure is not limited thereto. In some embodiments, a heating unit (not shown) and a rotation unit (not shown) are also provided below the support platform 110. The heating unit may be, for example, used to heat the support platform 110 to a suitable temperature, so that the substrate SB reaches a reaction temperature for performing, for example, a MOCVD process. The rotation unit may be used, for example, to rotate the substrate SB during a reaction process. In the embodiment, the reactor 10a may further include a vacuum pump VP1 and a pressure controller PC1. The vacuum pump VP1 is connected to the reaction chamber 100 through, for example, a gas flow path GP1 including an inlet valve I1 and an outlet valve O1, and may be used, for example, to evacuate the reaction chamber 100 when a reaction is taking place. The pressure controller PC1 is connected to the vacuum pump VP1 and the reaction chamber 100 through, for example, the gas flow path GP1 to control a pressure in the reaction chamber 100. It should be noted that although FIG. 1A shows that the reactor 10a includes one reaction chamber 100, the reactor 10a may also include a plurality of reaction chambers 100.

The gas chamber 200 is, for example, disposed above the reaction chamber 100. In the embodiment, the gas chamber 200 includes a showerhead 210. The showerhead 210 may include, for example, a cover plate 212 and a gas distribution unit 214. The cover plate 212 may be, for example, plate-shaped and include stainless steel, aluminum alloy or other suitable metal materials, but the disclosure is not limited thereto. The gas distribution unit 214 is, for example, disposed below the cover plate 212. In some embodiments, the gas distribution unit 214 includes a plurality of gas flow paths (not shown). The plurality of gas flow paths are, for example, respectively connected to the precursor source 300 and the carrier gas source 400 to transport raw materials provided by the precursor source 300 and the carrier gas source 400 to the substrate SB to perform the MOCVD process, but the disclosure is not limited thereto. In some embodiments, the showerhead 210 may also include a cooling unit (not shown). The cooling unit may be, for example, used to cool a high temperature generated by the heating unit heating the support platform 110, so as to reduce a possibility that the showerhead 210 is affected by the high temperature and causes abnormalities.

The precursor source 300 is connected to the gas chamber 200 to, for example, provide reaction precursors to the gas chamber 200. In the embodiment, the precursor source 300 includes a first precursor source 310 and a second precursor source 320, but the disclosure is not limited thereto. A precursor PS1 provided by the first precursor source 310 includes, for example, organic metal. For example, the precursor PS1 provided by the first precursor source 310 may include Ga(CH₃)₃, In(CH₃)₃, Al(C₂H₅)₃, Te(C₂H₅)₂, Zn(C₂H₅)₂, other suitable organic metals or combinations thereof. A precursor PS2 provided by the second precursor source 320 includes, for example, a hydride or a halide. For example, the precursor PS2 provided by the second precursor source 320 may include NH₃, AsH₃, PH₃, SiH₄, Si₂H₆, H₂Se, CBr₄, other suitable hydrides or halides or combinations thereof. It should be note that although FIG. 1A shows that the precursor source 300 includes the first precursor source 310 and the second precursor source 320, the precursor source 300 may also include a plurality of first precursor sources 310 and a plurality of second precursor sources 320.

The carrier gas source 400 is connected to the gas chamber 200 to, for example, provide a carrier gas CG to the gas chamber 200. The carrier gas CG provided by the carrier gas source 400 includes, for example, inert gas or other gases that do not react with the precursor PS1 and the precursor PS2. For example, the carrier gas CG provided by the carrier gas source 400 may include nitrogen (N₂), hydrogen (H₂), other suitable gases, or a combination thereof.

In the embodiment, the reactor 10a may further include a precursor flow path PP1, a precursor flow path PP2, a carrier gas flow path CP, and a mass flow controller MFC, but the disclosure is not limited thereto.

The precursor flow path PP1 may be, for example, configured to connect the first precursor source 310 to the gas chamber 200, and the precursor flow path PP2 may be, for example, configured to connect the second precursor source 320 to the gas chamber 200, and the carrier gas flow path CP may be, for example, configured to connect the carrier gas source 400 to gas chamber 200. The mass flow controller MFC connects the precursor source 300 and the gas chamber 200 through the precursor flow path PP1 and the precursor flow path PP2, and connects the carrier gas source 400 and the gas chamber 200 through the carrier gas flow path CP, so as to control a flow rate of each gas in the precursor flow path PP1, the precursor flow path PP2 and the carrier gas flow path CP flowing into the gas chamber 200.

In some embodiments, inlets of the precursor flow path PP1, the precursor flow path PP2 and the carrier gas flow path CP are respectively provided with an inlet valve IV1, an inlet valve IV2, and an inlet valve IV3, which are used to control opening or closing of the corresponding gas flow paths. In addition, in some embodiments, outlets of the precursor flow path PP1, the precursor flow path PP2 and the carrier gas flow path CP are respectively provided with an outlet valve OV1, an outlet valve OV2, and an outlet valve OV3, which are used to control opening or closing of each gas from the mass flow controller MFC to the gas chamber 200.

The recycling chamber 500 is, for example, connected to the reaction chamber 100 and the precursor flow path PP1. Referring to FIG. 1B, in the embodiment, the reactor 10a further includes a recycling flow path RP, a loop flow path LP, a discharge flow path DP, a solution flow inlet SP, and a grinding material flow inlet AP, and the recycling chamber 500 includes a recycling chamber body 510, a filter unit 520, a rotation unit 530, and a heating unit 540. An inlet and an outlet of the recycling flow path RP are, for example, respectively provided with an inlet valve IV4 and an outlet valve OV4, which are used to control opening or closing of the recycling flow path RP. An inlet and an outlet of the loop flow path LP are, for example, respectively provided with an inlet valve IV5 and an outlet valve OV5, which are used to control opening or closing of the loop flow path LP. An inlet of the discharge flow path DP is, for example, provided with an inlet valve IV6 for controlling opening or closing of the discharge flow path DP.

The recycling flow path RP is configured to, for example, connect the recycling chamber body 510 with the reaction chamber 100 to transport tail gas TG from the reaction chamber 100 into the recycling chamber 500. The loop flow path LP is configured to, for example, connect the recycling chamber body 510 with the first precursor source 310 to transport a precursor PS1′ formed after the tail gas TG is processed by the recycling chamber 500 to the precursor flow path PP1, such that the precursor PS1′ and the precursor PS1 together flow into the gas chamber 200 again. The discharge flow path DP is, for example, configured to be connected to the recycling chamber body 510 to discharge a remaining gas RG formed after the tail gas TG is processed by the recycling chamber 500, where the remaining gas RG may be reused in other processes or discarded, which is not limited by the disclosure. The solution flow inlet SP and the grinding material flow inlet AP may, for example, respectively provide a solution and a grinding material to the recycling chamber body 510, which are used for a treatment process of the tail gas TG performed by the recycling chamber 500, which will be described in detail in the following embodiments. The filter unit 520 is, for example, disposed in the recycling chamber body 510, and may be configured to discharge impurities during the process of processing the tail gas TG, but the disclosure is not limited thereto. The rotation unit 530 is, for example, disposed below the recycling chamber body 510 and connected thereto, and may be used to, for example, rotate the recycling chamber 500 when processing the tail gas TG. The heating unit 540 is, for example, disposed around the recycling chamber body 510, and may be configured to heat the recycling chamber body 510 to a suitable temperature during the process of processing the tail gas TG to, for example, oxidize some substances in the tail gas TG to achieve an effect of removing specific functional groups.

In the embodiment, the reactor 10a may further include a vacuum pump VP2 and a pressure controller PC2. The vacuum pump VP2 is connected to the recycling chamber 500 through, for example, the gas flow path GP2 including the inlet valve 12 and the outlet valve O2, and may be configured to, for example, evacuate the recycling chamber 500 during the process of processing the tail gas TG. The pressure controller PC2 connects the vacuum pump VP2 and the recycling chamber 500 through, for example, the gas flow path GP2 to control a pressure in the recycling chamber 500.

FIG. 1C is a partial schematic diagram of an embodiment of a semiconductor element formed by using the reactor of FIG. 1A. FIG. 1D is a partial schematic diagram of an embodiment of a semiconductor film layer of the semiconductor element in FIG. 1C, and FIG. 1E is a partial schematic diagram of another embodiment of the semiconductor film layer of the semiconductor element in FIG. 1C.

Referring to FIG. 1C, a semiconductor element shown in FIG. 1C is a light-emitting diode LED. In the embodiment, the light-emitting diode LED is sequentially stacked in the direction Z with a substrate 1, a nucleation layer 2, a buffer layer 3, a non-doped layer 4a, an n-type doped layer 4b, a heterojunction 5, and a quantum well layer 6, an electron blocking layer 7, a p-type doped layer 4c and a p-type heavily doped layer 4d, but the disclosure is not limited thereto.

In the embodiment, a material of the substrate 1 includes silicon, a material of the nucleation layer 2 includes aluminum nitride, a material of the buffer layer 3 includes aluminum gallium nitride, a material of the non-doped layer 4a includes i-type gallium nitrogen, a material of the n-type doped layer 4b includes n-type gallium nitride, a material of the heterojunction 5 includes indium gallium nitride/gallium nitride short period superlattice, a material of the quantum well layer 6 includes indium gallium nitride/gallium nitride multi-quantum well, a material of the electron blocking layer 7 includes p-type aluminum gallium nitride, a material of the p-type doped layer 4c includes p-type gallium nitride, and a material of the p-type heavily doped layer 4d includes p-type heavily doped gallium nitride, but the disclosure is not limited thereto.

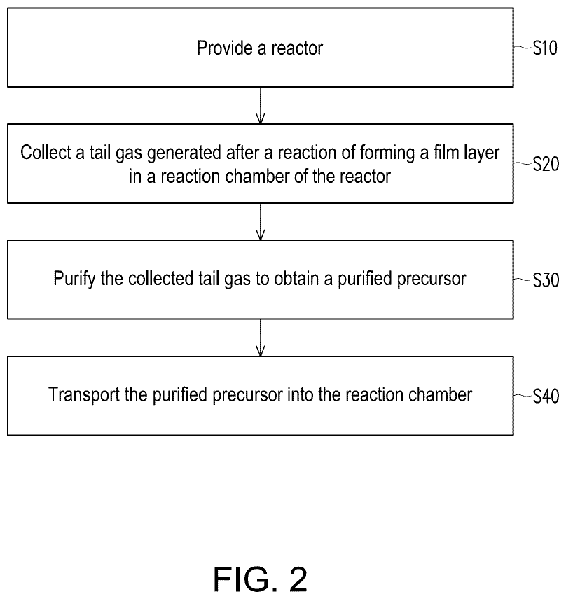

In the embodiment, the buffer layer 3 in the light-emitting diode LED is formed by using the above-mentioned reactor 10a, which may be formed by performing following steps shown in FIG. 2, but the disclosure is not limited thereto. Impurities included in the buffer layer 3 may have a concentration gradient. In detail, the impurities included in the buffer layer 3 increase along a growth direction (a direction Z) of the buffer layer 3, as shown in FIG. 1D. In addition, the impurities may exist in the form of particles IM, but the disclosure is not limited thereto. The reason why the impurities in the buffer layer 3 have the concentration gradient will be described in the following embodiments.

FIG. 2 is a schematic flowchart of using recycled gas to form a film layer in a semiconductor manufacturing process according to an embodiment of the disclosure.

Referring to FIG. 2, in step S10, the reactor 10a is provided. The reactor 10a may be, for example, a MOCVD reactor. Regarding the arrangement relationships and uses of the various components included in the reactor 10a, reference may be made to the above embodiments, which will not be repeated here.

In step S20, the tail gas TG generated after the reaction of forming a film layer in the reactor 10a is collected. In the embodiment, the formed film layer is the buffer layer 3 of the light-emitting diode LED shown in FIG. 1C, but the disclosure is not limited thereto. In addition, the reaction carried out in the reactor 10a may be, for example, a MOCVD process. In the embodiment, the collected tail gas TG may include the unreacted precursor PS1, the precursor PS2 and the carrier gas CG, where the precursor PS1 is Ga(CH₃)₃ and Al(C₂H₅)₃, the precursor PS2 is NH₃, and the carrier gas CG is N₂ and H₂, but the disclosure is not limited thereto. In some embodiments, the tail gas TG may be collected through the recycling chamber 500 and the recycling flow path RP connected to the reaction chamber 100. The description of the recycling chamber 500 and the recycling flow path RP may refer to the above embodiment, and detail thereof will not be repeated here.

In step S30, the collected tail gas TG is purified to obtain the purified precursor PS1′. In the embodiment, the purified precursor PS1′ includes Ga(CH₃)₃. In some embodiments, the collected tail gas TG may be purified through the recycling chamber 500. For introduction of purification of the tail gas TG in the recycling chamber 500, reference may be made to the above embodiments, and details will not be repeated here. It should be noted that, in addition to Ga(CH₃)₃, the purified precursor PS1′ may also include some impurities (such as hydrocarbons such as methyl and/or by-products presented in the form of particles as shown in FIG. 1E).

In some embodiments, in the step of purifying the collected tail gas (step S30), it also includes separating a carrier gas from the tail gas TG. The carrier gas may be separated using a reactor 10b of the following embodiment, but the disclosure is not limited thereto.

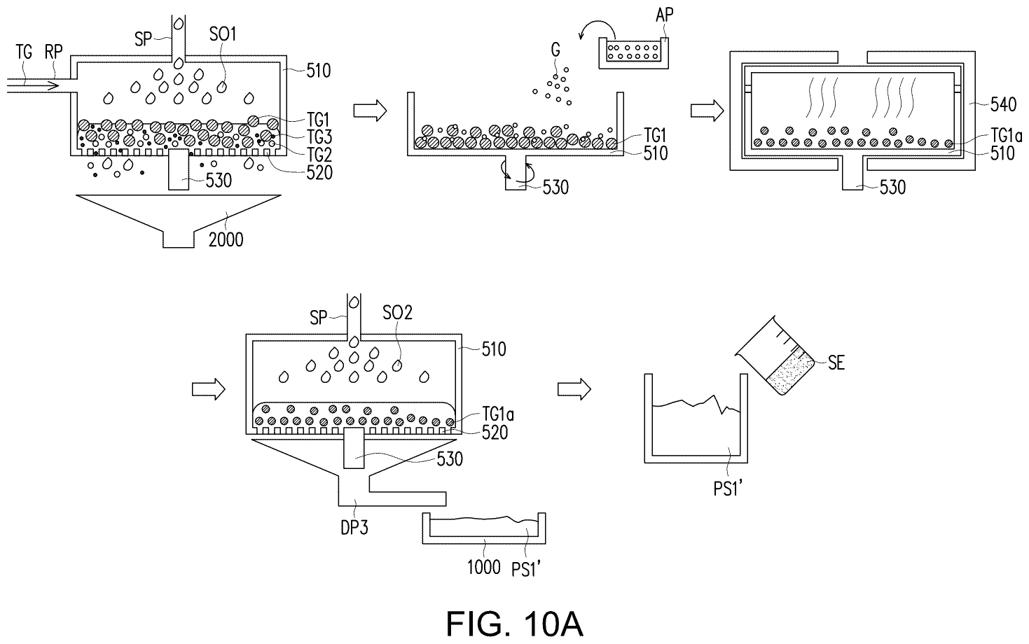

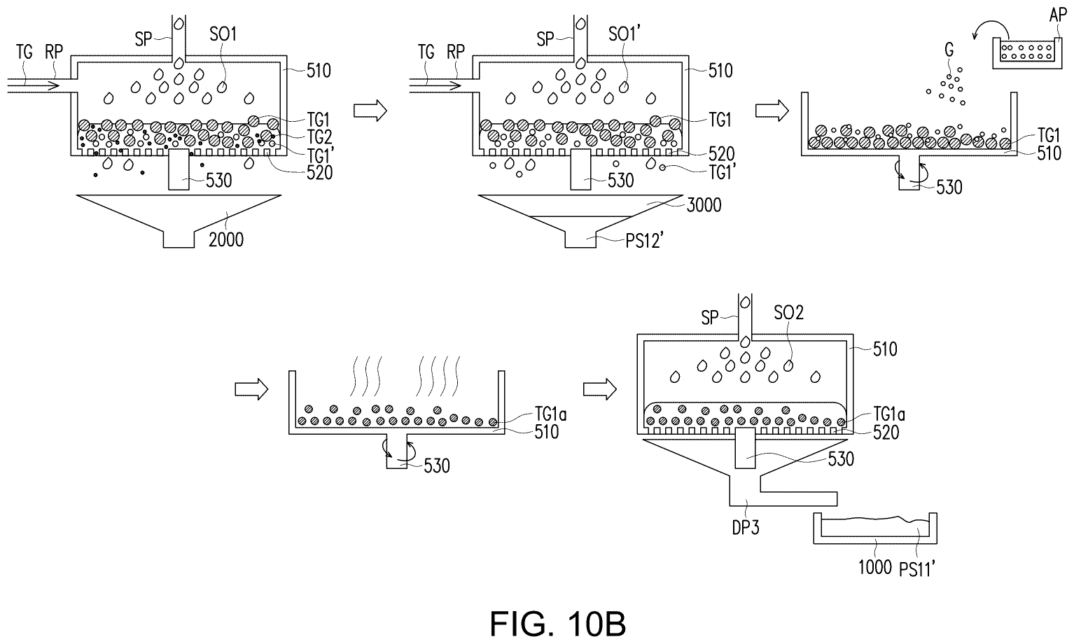

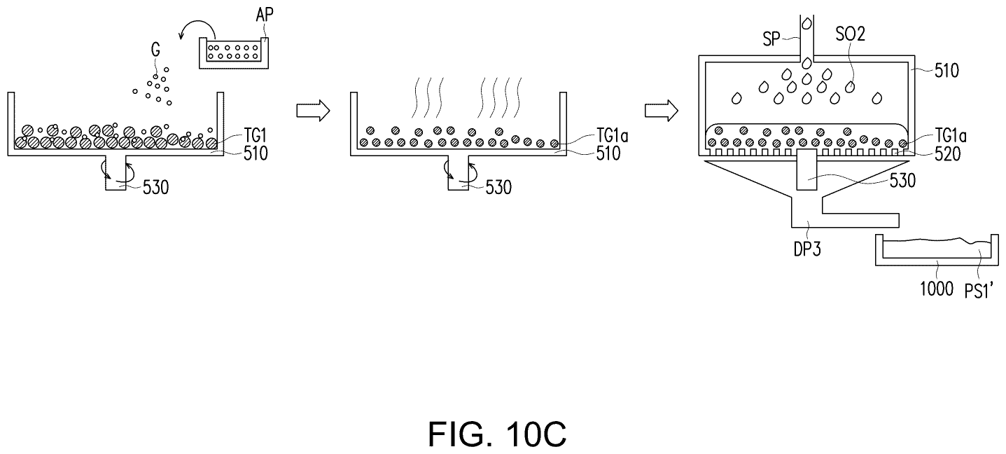

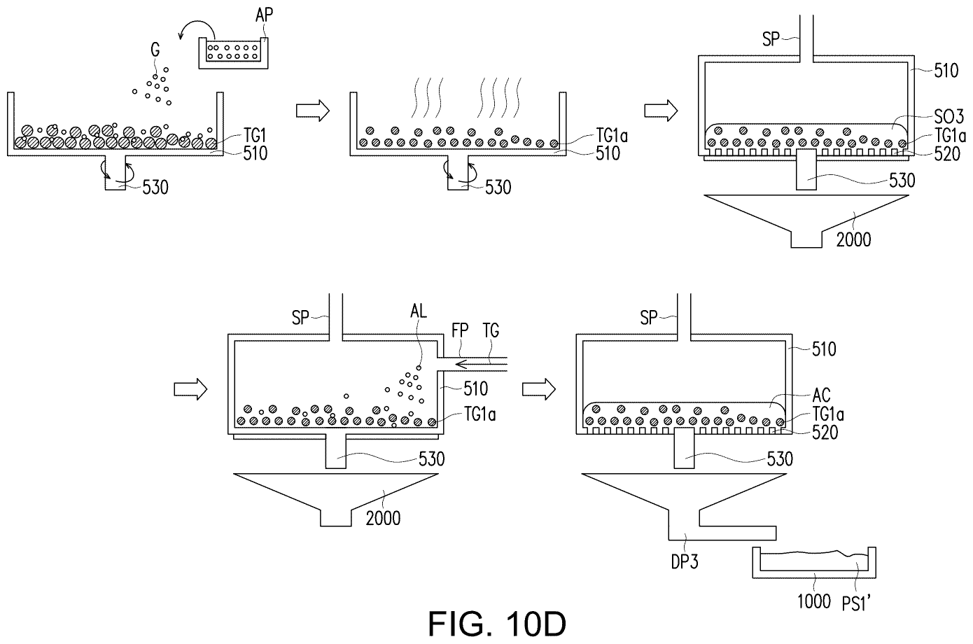

In some embodiments, the step of purifying the collected tail gas (step S30) may include performing a process of the embodiment shown in FIG. 10A to FIG. 10D below, but the disclosure is not limited thereto.

In step S40, the purified precursor PS1′ is transported into the reaction chamber 100. In some embodiments, the purified precursor PS1′ may be provided to the reaction chamber 100 in real time through the precursor flow path PP1 connected to the loop flow path LP. For introduction of the loop flow path LP, reference may be made to the above-mentioned embodiments, which will not be repeated here. In the embodiment, the purified precursor PS1′ is transferred into the reaction chamber 100 in real time to carry out the reaction of forming the buffer layer 3 of the light-emitting diode LED shown in FIG. 1C, but the disclosure is not limited thereto.

In some embodiments, before transferring the purified precursor PS1′ into the reaction chamber 100, a reactor 10c of the following embodiment may be used to mix the purified precursor PS1′ with an organic solvent to form a liquid precursor, but the disclosure is not limited thereto.

In some embodiments, in step S40, a reactor 10d of the following embodiment may be used to perform multiple purifications to obtain a plurality of purified precursors PS1′, and the plurality of purified precursors PS1′ are different from each other, but the disclosure is not limited thereto.

Based on the above, after step S10 is performed, at least one cycle of steps S20 to S40 is performed to form the buffer layer 3 in the light-emitting diode LED. It should be noted that since the purified precursor PS1′ includes a part of impurities, and its concentration in the reaction chamber 100 may increase along with a reaction time, the impurities included in the buffer layer 3 may have the concentration gradient. In detail, the impurities included in the buffer layer 3 may increase along a growth direction (direction Z) of the buffer layer 3, as shown in FIG. 1D and FIG. 1E.

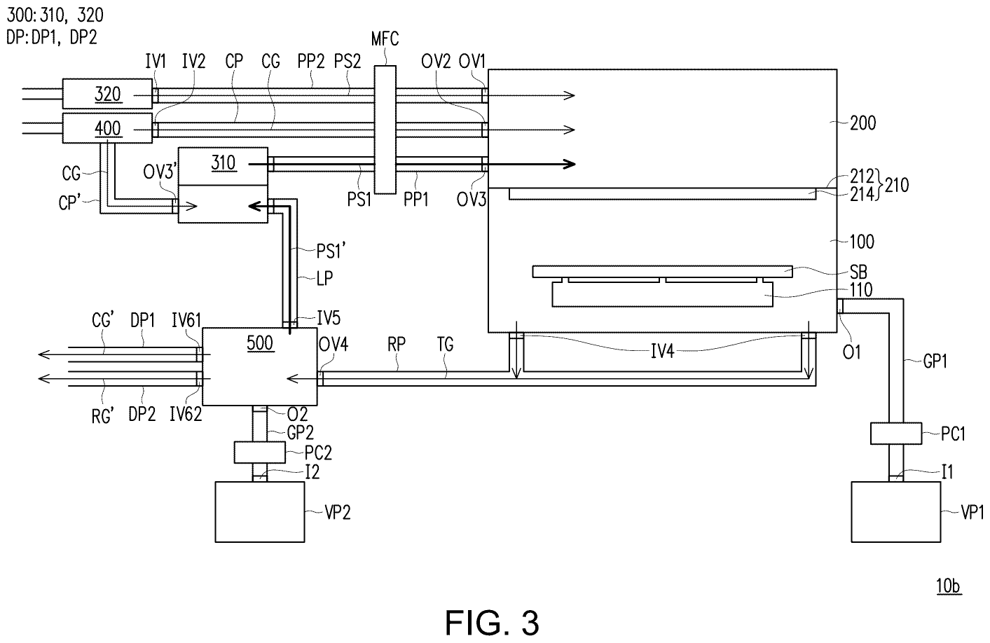

FIG. 3 is a schematic diagram of a reactor according to a second embodiment of the disclosure. It should be noted that the embodiment of FIG. 3 may use the component referential numbers and a part of the content of the embodiment of FIG. 1A, where the same or similar referential numbers are used to represent the same or similar components, and descriptions of the same technical content are omitted.

Referring to FIG. 3, a main difference between the reactor 10b of the embodiment and the above-mentioned reactor 10a is that the carrier gas source 400 is further connected to the first precursor source 310, for example.

In detail, in the embodiment, the reactor 10b further includes a carrier gas flow path CP′. The carrier gas flow path CP′ is configured to, for example, connect the carrier gas source 400 with the first precursor source 310. In some embodiments, an outlet of the carrier gas flow path CP′ has an outlet valve OV3′, which is used to control opening or closing of the carrier gas flow path CP′. Furthermore, in the embodiment, the loop flow path LP is configured to connect the recycling chamber 500 to the first precursor source 310.

In addition, in the embodiment, the discharge flow path DP includes, for example, a discharge flow path DP1 and a discharge flow path DP2. The discharge flow path DP1 is configured to, for example, discharge a carrier gas CG′ formed after the tail gas TG is processed through the recycling chamber 500s, where the carrier gas CG′ may be reused in the process or stored, which is not limited by the disclosure. The discharge flow path DP2 is configured to, for example, discharge a remaining gas RG′ formed after the tail gas TG is processed through the recycling chamber 500, where the remaining gas RG′ may be reused in other processes or discarded, which is not limited by the disclosure. An inlet of the discharge flow path DP1 and an inlet of the discharge flow path DP2 are respectively provided with an inlet valve IV61 and an inlet valve IV62, which are respectively used for controlling opening or closing of the discharge flow path DP1 and the discharge flow path DP2.

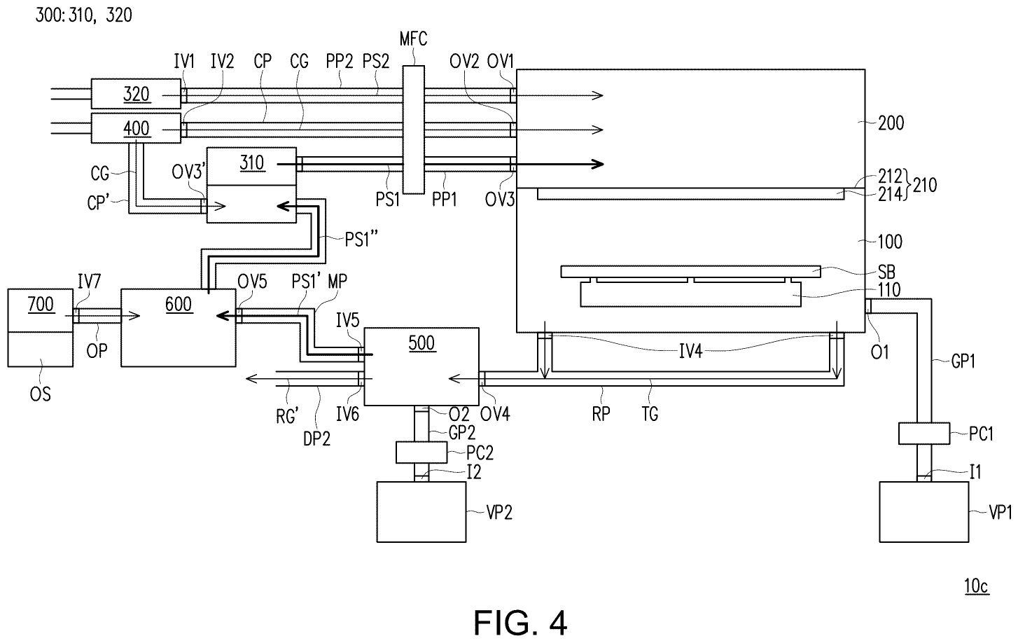

FIG. 4 is a schematic diagram of a reactor according to a third embodiment of the disclosure. It should be noted that the embodiment of FIG. 4 may use the component referential numbers and a part of the content of the embodiment of FIG. 3, where the same or similar referential numbers are used to represent the same or similar components, and the description of the same technical content is omitted.

Referring to FIG. 4, a main difference between a reactor 10c of the embodiment and the above-mentioned reactor 10b is that the reactor 10c of the embodiment further includes a mixing chamber 600 and an organic solvent source 700.

In detail, in the embodiment, the reactor 10c further includes a mixing path MP and an organic solvent path OP.

The mixing path MP is, for example, configured to connect the mixing chamber 600 and the recycling chamber 500. An inlet and an outlet of the mixing path MP are respectively provided with an inlet valve IV5 and an outlet valve OV5, which are used to control opening or closing the mixing path MP. Furthermore, in the embodiment, the loop flow path LP is configured to connect the mixing chamber 600 to the first precursor source 310.

The organic solvent path OP is configured to, for example, connect the organic solvent source 700 to the mixing chamber 600. An inlet of the organic solvent path OP is, for example, provided with an inlet valve IV7, which is used to control opening or closing of the organic solvent path OP.

Through the arrangement of the mixing chamber 600 and the organic solvent source 700, the precursor PS1′ formed after the tail gas TG is processed through the recycling chamber 500 and an organic solvent OS provided by the organic solvent source 700 may be transferred to the mixing chamber 600, and the precursor PS1′ and the organic solvent OS may be mixed in the mixing chamber 600 to form a liquid precursor PS1″, and the liquid precursor PS1″ is provided to the first precursor source 310 through the loop flow path LP for real-time transmission to the gas chamber 200.

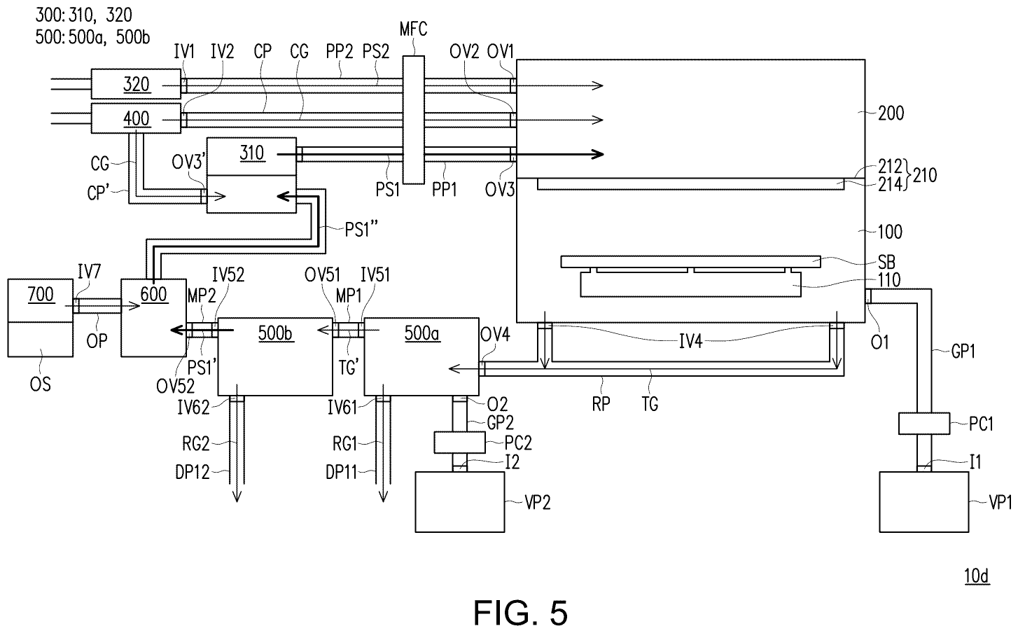

FIG. 5 is a schematic diagram of a reactor according to a fourth embodiment of the disclosure. It should be noted that the embodiment of FIG. 5 may use the component referential numbers and a part of the content of the embodiment of FIG. 4, where the same or similar referential numbers are used to represent the same or similar components, and the description of the same technical content is omitted.

Referring to FIG. 5, a main difference between a reactor 10d of the embodiment and the above-mentioned reactor 10c is that the reactor 10d of the embodiment includes a plurality of recycling chambers 500.

In detail, in the embodiment, the plurality of recycling chambers 500 may include a first recycling chamber 500a and a second recycling chamber 500b, and the mixing path MP includes a first mixing path MP1 and a second mixing path MP1.

The first mixing path MP1 is configured to, for example, connect the first recycling chamber 500a to the reaction chamber 100, and the second mixing path MP2 is, for example, configured to connect the second recycling chamber 500b to the first recycling chamber 500a. An inlet and an outlet of the first mixing path MP1 are, for example, respectively provided with an inlet valve IV51 and an outlet valve OV51, which are used to control opening or closing of the first mixing path MP1. An inlet and an outlet of the second mixing path MP2 are, for example, respectively provided with an inlet valve IV52 and an outlet valve OV52, which are used to control opening or closing of the second mixing path MP2. In addition, in the embodiment, the discharge flow path DP1 includes a first discharge flow path DP11 and a second discharge flow path DP12. The first discharge flow path DP11 is, for example, configured to connect the first recycling chamber 500a to discharge the remaining gas RG1 formed after the tail gas TG is processed through the first recycling chamber 500a, where the remaining gas RG1 may be reused in other processes or discarded. The second discharge flow path DP12 is, for example, configured to connect the second recycling chamber 500b to discharge the remaining gas RG2 formed after the tail gas TG′ is processed through the second recycling chamber 500b, where the remaining gas RG2 may be reused in other processes or discarded.

Through the arrangement of the plurality of recycling chambers 500, the precursor PS1′ may be purified by multiple times, so that the impurities in the precursor PS1′ may be further reduced.

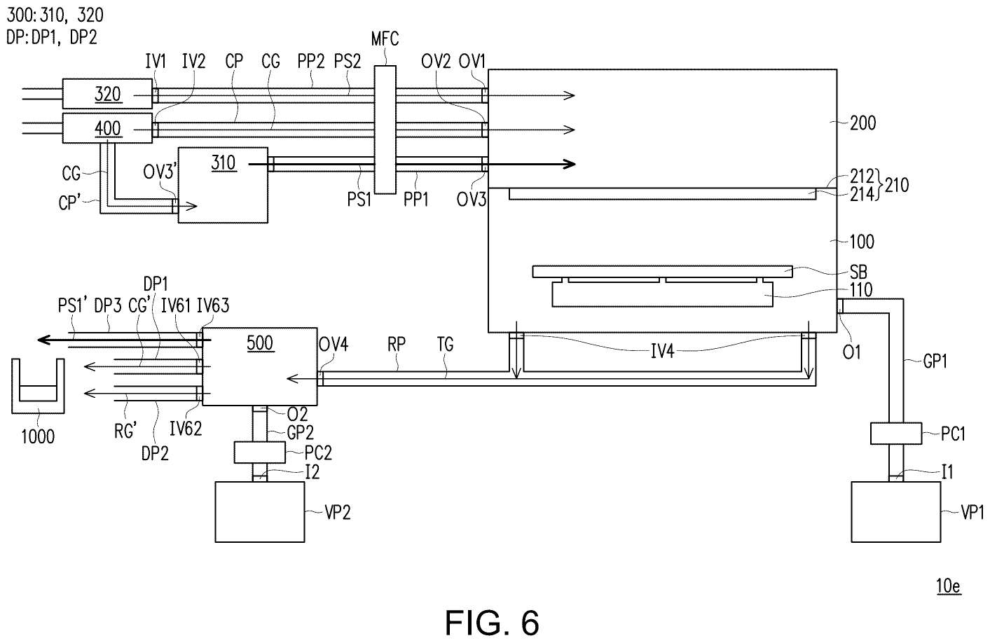

FIG. 6 is a schematic diagram of a reactor according to a fifth embodiment of the disclosure. It should be noted that the embodiment of FIG. 6 may use the component referential numbers and a part of the content of the embodiment of FIG. 3, where the same or similar referential numbers are used to represent the same or similar components, and the description of the same technical content is omitted.

Referring to FIG. 6, a main difference between a reactor 10e of the embodiment and the above-mentioned reactor 10b is that the reactor 10e of the embodiment does not include the loop flow path LP.

In detail, in the embodiment, the reactor 10e further includes a discharge flow path DP3. The discharge flow path DP3 is, for example, configured to connect the recycling chamber 500 to discharge the precursor PS1′ formed after the tail gas TG is processed through the recycling chamber 500, where the discharged precursor PS1′ may be collected by a container 1000. Since the precursor PS1′ includes impurities, the precursor PS1′ discharged from the discharge flow path DP3 may be subsequently purified and returned to the reaction chamber 100, or used in other processes. An inlet of the discharge flow path DP3 is, for example, provided with an inlet valve IV63, which is used to control opening and closing of the discharge flow path DP3.

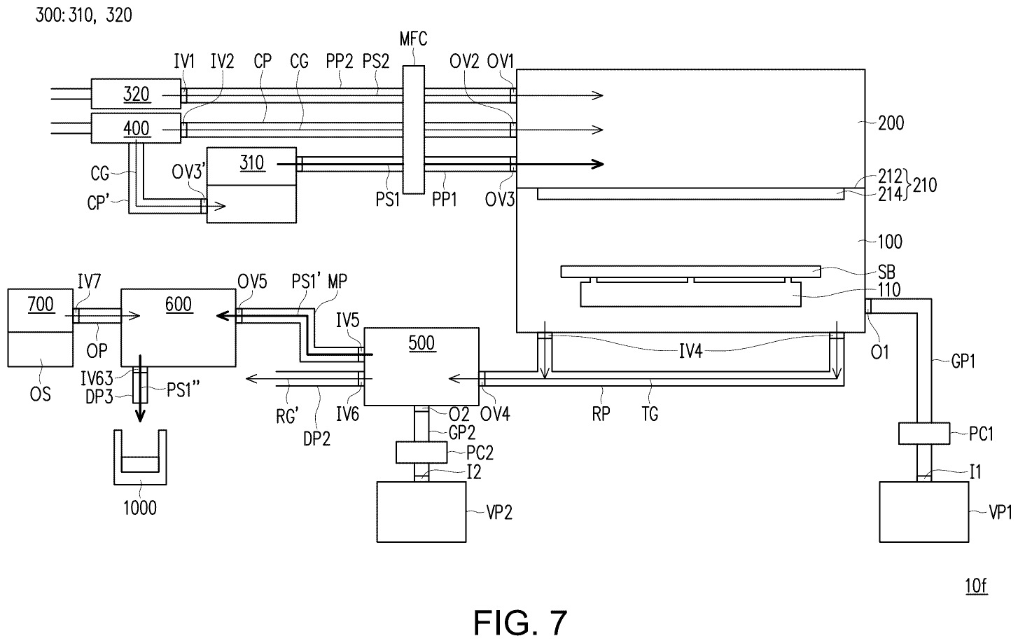

FIG. 7 is a schematic diagram of a reactor according to a sixth embodiment of the disclosure. It should be noted that the embodiment of FIG. 7 may use the component referential numbers and a part of the content of the embodiment of FIG. 4, where the same or similar referential numbers are used to represent the same or similar components, and the description of the same technical content is omitted.

Referring to FIG. 7, a main difference between a reactor 10f of the embodiment and the above-mentioned MOCVD reactor 10c is that the reactor 10f of the embodiment does not include the loop flow path LP.

In detail, in the embodiment, the reactor 10f further includes a discharge flow path DP3. The discharge flow path DP3 is, for example, configured to connect the mixing chamber 600, and the precursor PS1′ formed after the tail gas TG is processed through the recycling chamber 500 may be mixed with the organic solvent OS provided by the organic solvent source 700 in the mixing chamber 600 to form a liquid precursor PS1″, and the liquid precursor PS1″ may be discharged through the discharge flow path DP3, where the discharged liquid precursor PS1″ may be collected by the container 1000. Since the liquid precursor PS1″ includes impurities, the liquid precursor PS1″ discharged from the discharge flow path DP3 may be subsequently purified and returned to the reaction chamber 100, or used in other processes. An inlet of the discharge flow path DP3 is, for example, provided with an inlet valve IV63, which is used to control opening and closing of the discharge flow path DP3.

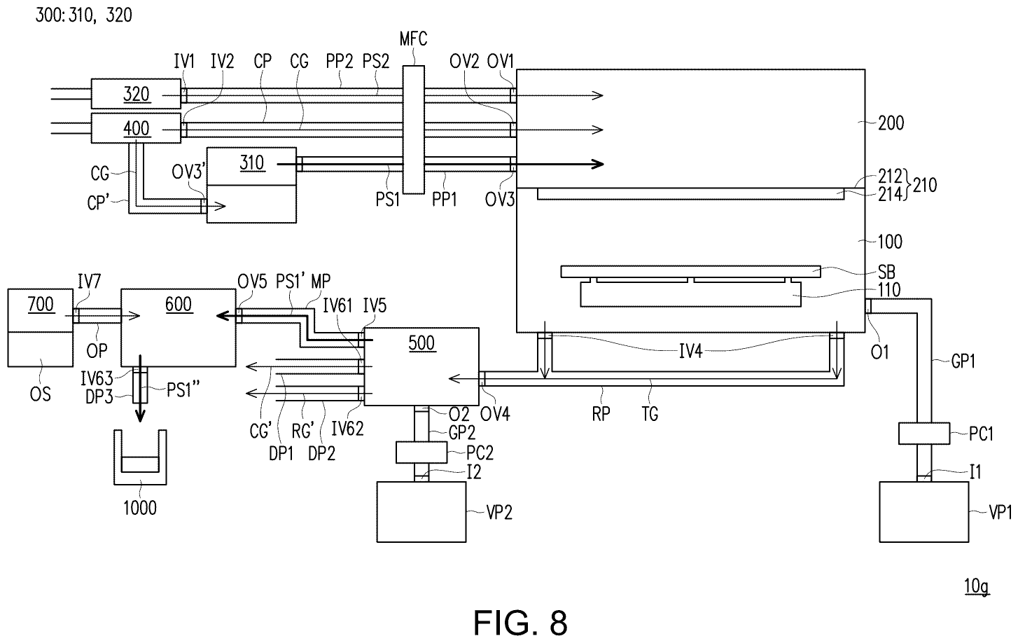

FIG. 8 is a schematic diagram of a reactor according to a seventh embodiment of the disclosure. It should be noted that the embodiment of FIG. 8 may use the component referential numbers and a part of the content of the embodiment of FIG. 7, where the same or similar referential numbers are used to represent the same or similar components, and the description of the same technical content is omitted.

Referring to FIG. 8, a main difference between a reactor 10g of the embodiment and the above-mentioned reactor 10f is that the discharge flow path DP in the reactor 10g of the embodiment includes a discharge flow path DP1 and a discharge flow path DP2.

In the embodiment, the discharge flow path DP1 is configured to, for example, discharge the carrier gas CG′ formed after the tail gas TG is processed through the recycling chamber 500, where the carrier gas CG′ may be reused in the process or stored, which is not limited by the disclosure. The discharge flow path DP2 is configured to, for example, discharge the remaining gas RG′ formed after the tail gas TG is processed through the recycling chamber 500, where the remaining gas RG′ may be reused in other processes or discarded, which is not limited by the disclosure. An inlet of the discharge flow path DP1 and an inlet of the discharge flow path DP2 are, for example, respectively provided with an inlet valve IV61 and an inlet valve IV62, which are used to respectively control opening and closing of the discharge flow path DP1 and the discharge flow path DP2.

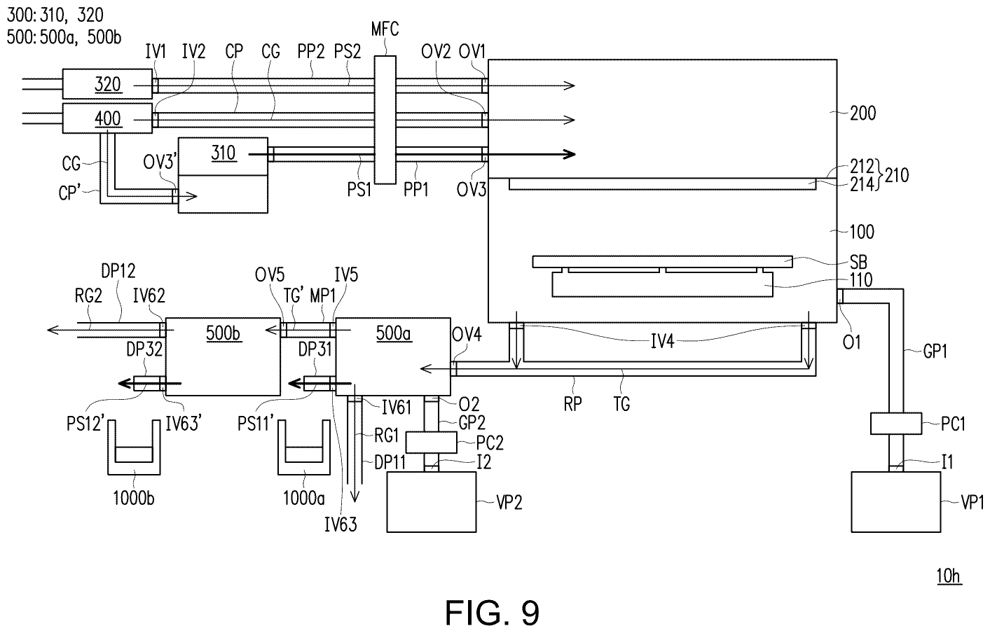

FIG. 9 is a schematic diagram of a reactor according to an eighth embodiment of the disclosure. It should be noted that the embodiment of FIG. 9 may use the component referential numbers and a part of the content of the embodiment of FIG. 5, where the same or similar referential numbers are used to represent the same or similar components, and descriptions of the same technical content are omitted.

Referring to FIG. 9, a main difference between a reactor 10h of the embodiment and the above-mentioned reactor 10d is that the reactor 10h of the embodiment does not include the loop flow path LP.

In detail, in the embodiment, the reactor 10h further includes a discharge flow path DP3.

The discharge flow path DP3 includes, for example, a first discharge flow path DP31 and a second discharge flow path DP32. The first discharge flow path DP31 is, for example, configured to connect the first recycling chamber 500a to discharge a precursor PS11′ formed after the tail gas TG is processed through the first recycling chamber 500a, where the discharged precursor PS11′ may be collected by the container 1000a. The second discharge flow path DP32 is configured to, for example, connect the second recycling chamber 500b to discharge a precursor PS12′ formed after the tail gas TG′ is processed through the second recycling chamber 500b, where the discharged precursor PS12′ may be collected by the container 1000b. In the embodiment, the discharged precursor PS11′ and precursor PS12′ include different main components, thereby achieving the effect of respectively recycling different main components, but the disclosure is not limited thereto.

Since the precursor PS11′ and the precursor PS12′ respectively include impurities, the precursor PS11′ and the precursor PS12′ discharged from the discharge flow path DP3 may be subsequently purified and returned to the reaction chamber 100, or may be used in other processes. An inlet of the first discharge flow path DP31 and an inlet of the second discharge flow path DP32 are, for example, respectively provided with an inlet valve IV63 and an inlet valve IV63′, which are used to respectively control opening and closing of the first discharge flow path DP31 and the second discharge flow path DP32.

FIG. 10A is a schematic flowchart of an embodiment of processing tail gas by using the recycling chamber in the reactor of FIG. 1A. It should be noted that the embodiment of FIG. 10A may use the component referential numbers and a part of the content of the embodiment of FIG. 1A, where the same or similar referential numbers are used to represent the same or similar components, and descriptions of the same technical content are omitted.

Referring to FIG. 10A, which shows that the tail gas TG may be processed according to the following process, where the tail gas TG includes, for example, a main component TG1 and impurities TG2 and TG3.

First, the tail gas TG is transported into the recycling chamber body 510 of the recycling chamber 500 through the recycling flow path RP, and a solution SO1 is transported into the recycling chamber body 510 through a solution flow inlet SP to leach the main component TG1 in the tail gas TG. After the tail gas TG is mixed with the solution SO1, the impurities TG2 and TG3 are discharged by using the filter unit 520 of the recycling chamber 500, where the discharged impurities TG2 and TG3 may be collected by a container 2000. In some embodiments, the solution SO1 may include water or suitable acids, but the disclosure is not limited thereto.

Then, a grinding material G is transported into the recycling chamber body 510 of the recycling chamber 500 through the grinding material flow inlet AP, and the rotation unit 530 is used to rotate the recycling chamber body 510 so that the grinding material G grinds the main component TG1, thereby achieving a physical catalytic effect. In some embodiments, sodium carbonate may be added before grinding the main component TG1, but the disclosure is not limited thereto.

Thereafter, the heating unit 540 is used to heat the main component TG1 in the recycling chamber body 510 to, for example, remove specific functional groups in the main component TG1 to form a main component TG1a.

Then, after the main component TG1a is formed, a solution SO2 is transported into the recycling chamber body 510 through the solution flow inlet SP to leach the precursor PS1′ in the main component TG1a. Afterwards, the filter unit 520 is used to discharge the precursor PS1′, where the discharged precursor PS1′ may be collected by the container 1000. In the embodiment, the main component TG1 is Ga(CH₃)₃. Therefore, the precursor PS1′ includes gallium after removing the methyl group, but the disclosure is not limited thereto. In some embodiments, the solution SO2 may include water or suitable acids, but the disclosure is not limited thereto.

Then, the precursor PS1′ in the container 1000 is extracted by using an extraction solution SE. In some embodiments, the extraction solution SE may include sulfuric acid or other suitable acids, but the disclosure is not limited thereto.

FIG. 10B is a schematic flowchart of another embodiment of processing tail gas by using the recycling chamber in the reactor of FIG. 1A. It should be noted that the embodiment of FIG. 10B may use the component referential numbers and a part of the content of the embodiment of FIG. 10A, where the same or similar referential numbers are used to represent the same or similar components, and descriptions of the same technical content are omitted.

Referring to FIG. 10B, a main process difference between the process shown in FIG. 10B and the process shown in FIG. 10A is that the tail gas TG is leached twice.

In detail, in the embodiment, the tail gas TG (including the main component TG1, a main component TG1′ and the impurity TG2) is transported into the recycling chamber body 510 of the recycling chamber 500 through the recycling flow path RP, and the solution SO1 is transported into the recycling chamber body 510 through the solution flow inlet SP to leach the main component TG1 and the main component TG1′ in the tail gas TG. After the tail gas TG is mixed with the solution SO1, the filter unit 520 of the recycling chamber 500 is used to discharge the impurity TG2, where the discharged impurity TG2 may be collected by the container 2000. In some embodiments, the solution SO1 may include water or suitable acids, but the disclosure is not limited thereto.

Then, the solution SO1′ is transported into the recycling chamber body 510 through the solution flow inlet SP again to leach the main component TG1. After the main component TG1, the main component TG1′ and the solution SO1′ are mixed, the filter unit 520 of the recycling chamber 500 is used to discharge the precursor PS12′ including the main component TG1′, where the discharged precursor PS12′ may be collected by a container 3000. In some embodiments, the solution SO1′ may include suitable acids, but the disclosure is not limited thereto.

In the embodiment, the main component TG1′ is In(CH₃)₃. Therefore, the precursor PS12′ includes indium after removing the methyl group, but the disclosure is not limited thereto.

In addition, in the embodiment, the main component TG1 is Ga(CH₃)₃. Therefore, the precursor PS11′ that is subsequently subjected to the above process includes gallium after removing the methyl group, but the disclosure is not limited thereto.

FIG. 10C is a schematic flowchart of still another embodiment of processing tail gas by using the recycling chamber in the reactor of FIG. 1A. It should be noted that the embodiment of FIG. 10C may use the component referential numbers and a part of the content of the embodiment of FIG. 10A, where the same or similar referential numbers are used to represent the same or similar components, and descriptions of the same technical content are omitted.

Referring to FIG. 10C, a main process difference between the process shown in FIG. 10C and the process shown in FIG. 10A is that the tail gas TG is not extracted.

FIG. 10D is a schematic flowchart of yet another embodiment of processing tail gas by using the recycling chamber in the reactor of FIG. 1A. It should be noted that the embodiment of FIG. 10D may use the component referential numbers and a part of the content of the embodiment of FIG. 10C, where the same or similar referential numbers are used to represent the same or similar components, and descriptions of the same technical content are omitted.

Referring to FIG. 10D, a main difference between the process shown in FIG. 10D and the process shown in FIG. 10C is that a dissolving step and a calcining step are further included.

In detail, after the main component TG1 in the recycling chamber body 510 is heated by the heating unit 540, the main component TG1a may be formed. Afterwards, a solution SO3 is transported into the recycling chamber body 510 through the solution flow inlet SP to dissolve the main component TG1a, where conditions of the dissolution process are 23 atm, 220° C. and 4 h, but the disclosure is not limited thereto. In some embodiments, the solution SO3 includes aqua regia, but the disclosure is not limited thereto.

Then, an alkali AL is transported into the recycling chamber body 510 through a feed port FP to perform a calcining step on the main component TG1a. The alkali AL may include, for example, lithium metaborate, sodium hydroxide, sodium carbonate or combinations thereof, but the disclosure is not limited thereto.

Afterwards, an acid AC is transported into the recycling chamber body 510 through the solution flow inlet SP to leach the precursor PS1′ in the main component TG1a. The acid AC may be, for example, a variety of suitable acids, but the disclosure is not limited thereto.

In summary, in some embodiments of the disclosure, the unreacted tail gas during the reaction may be recycled, and the precursor obtained after purifying the tail gas may be transported into the reaction chamber again for reaction. In this way, the amount of reaction precursors is reduced to reduce process costs.

Furthermore, in other embodiments of the disclosure, after recycling the unreacted tail gas during the reaction, the precursor obtained after purifying the tail gas may be stored for use in subsequent processes, thereby reducing the process cost of subsequent processes.

What is claimed is:

1. A method of forming a film layer by using a recycled gas, comprising:
providing a reactor;
collecting a tail gas generated after a reaction of forming the film layer in a reaction chamber of the reactor;
purifying the collected tail gas to obtain a purified precursor; and
transporting the purified precursor into the reaction chamber.

2. The method of forming the film layer by using the recycled gas as claimed in claim 1, wherein the purified precursor is transported into the reaction chamber in real time to carry out the reaction of forming the film layer.

3. The method of forming the film layer by using the recycled gas as claimed in claim 2, wherein the purified precursor comprises impurities, and a concentration of the impurities increases along a growth direction of the film layer.

4. The method of forming the film layer by using the recycled gas as claimed in claim 3, wherein the impurities are present in a form of particles.

5. The method of forming the film layer by using the recycled gas as claimed in claim 1, wherein before the step of transporting the purified precursor into the reaction chamber, the method further comprises:
mixing the purified precursor with an organic solvent to form a liquid precursor.

6. The method of forming the film layer by using the recycled gas as claimed in claim 5, wherein the liquid precursor is transported into the reaction chamber in real time to perform the reaction of forming the film layer.

7. The method of forming the film layer by using the recycled gas as claimed in claim 1, wherein the step of purifying the collected tail gas further comprises separating a carrier gas from the tail gas.

8. The method of forming the film layer by using the recycled gas as claimed in claim 1, wherein the collected tail gas is purified by multiple times to obtain a plurality of purified precursors, and the plurality of purified precursors are different from each other.

9. The method of forming the film layer by using the recycled gas as claimed in claim 1, wherein the step of purifying the collected tail gas comprises:
leaching a first main component in the tail gas;
grinding the first main component;
heating the first main component;
leaching a second main component from the first main component; and
extracting the second main component to obtain the purified precursor.

10. The method of forming the film layer by using the recycled gas as claimed in claim 9, wherein after the step of heating the first main component, the method further comprises:
dissolving the first main component; and
calcining the first main component.

11. A method of forming a semiconductor film layer by using a recycled gas, comprising:
providing a metal-organic chemical vapor deposition (MOCVD) reactor;
collecting a tail gas generated after a MOCVD process of forming the semiconductor film layer in a reaction chamber of the MOCVD reactor;
purifying the collected tail gas to obtain a purified precursor; and
transporting the purified precursor into the reaction chamber.

12. The method of forming the semiconductor film layer by using the recycled gas as claimed in claim 11, wherein the purified precursor is transported into the reaction chamber in real time to perform the MOCVD process of forming the semiconductor film layer.

13. The method of forming the semiconductor film layer by using the recycled gas as claimed in claim 11, wherein the semiconductor film layer comprises a buffer layer of a light-emitting diode, a material of the buffer layer comprises aluminum gallium nitride and a hydrocarbon, and a concentration of the hydrocarbon increases along a growth direction of the buffer layer.

14. The method of forming the semiconductor film layer by using the recycled gas as claimed in claim 13, wherein the hydrocarbon comprises methyl groups.

15. The method of forming the semiconductor film layer by using the recycled gas as claimed in claim 11, wherein the purified precursor comprises gallium, indium or a combination thereof.

16. The method of forming the semiconductor film layer by using the recycled gas as claimed in claim 11, wherein a first precursor in the MOCVD process comprises Ga(CH₃)₃, In(CH₃)₃, Al(C₂H₅)₃, Te(C₂H₅)₂, Zn(C₂H₅)₂, or combinations thereof.

17. The method of forming the semiconductor film layer by using the recycled gas as claimed in claim 11, wherein a second precursor in the MOCVD process comprises NH₃, AsH₃, PH₃, SiH₄, Si₂H₆, H₂Se, CBr₄, other suitable hydrides or halides or combinations thereof.

18. The method of forming the semiconductor film layer by using the recycled gas as claimed in claim 11, wherein a carrier gas in the MOCVD process comprises nitrogen (N₂), hydrogen (H₂) or a combination thereof.

19. The method of forming the semiconductor film layer by using the recycled gas as claimed in claim 11, wherein before the step of transporting the purified precursor into the reaction chamber, the method further comprises:
mixing the purified precursor with an organic solvent to form a liquid precursor.

20. The method of forming the semiconductor film layer by using the recycled gas as claimed in claim 19, wherein the liquid precursor is transported into the reaction chamber in real time to perform the MOCVD process of forming the semiconductor film layer.
